(19) United States
(12) Patent Application Publication
(10) Pub. No.: US 2025/0210941 A1
(43) Pub. Date: Jun. 26, 2025

(54) STACKED LASER ARRANGEMENT AND METHOD FOR PRODUCING SAME

(71) Applicant: ams-OSRAM International GmbH, Regensburg (DE)

(72) Inventors: Markus HORN, Ergoldsbach (DE); Martin BEHRINGER, Regensburg (DE); Joerg Erich SORG, Regensburg (DE); Nicole BERNER, Walderbach (DE); Erik HEINEMANN, Regensburg (DE); Markus RICHTER, Burglengenfeld (DE); Andreas ROZYNSKI, Regensburg (DE)

(73) Assignee: ams-OSRAM International GmbH, Regensburg (DE)

(21) Appl. No.: 18/849,066

(22) PCT Filed: Mar. 24, 2023
(86) PCT No.: PCT/EP2023/057702

§ 371 Date: Sep. 20, 2024

(30) Foreign Application Priority Data
Mar. 24, 2022 (DE) 10 2022 106 938.9

(51) Int. Cl. H01S 5/40; H01S 5/026

(52) U.S. Cl. CPC H01S 5/4093; H01S 5/0261; H01S 2301/17

(57) ABSTRACT

The invention relates to a stacked laser arrangement, including a first laser device having a light exit side and a semiconductor body which forms a resonator and has an active zone and two main sides and side faces arranged substantially perpendicular thereto; wherein the laser device has at least one contact region on a first of the two main sides. Moreover, a first spacer having a first contact main side and a contact side face is provided, with the contact main side having at least one contact line which leads from a contact region to a connection area on or adjacent to the contact side face. With its first main side facing the first contact main side, the first laser device is fastened to the first spacer such that the at least one contact region is electrically connected to the contact region of the first contact main side, and the side faces of the first laser device are spaced apart from the contact side face.

### CROSS-REFERENCE TO RELATED APPLICATIONS

The present application is a national stage entry from International Application No. PCT/EP2023/057702, filed on Mar. 24, 2023, published as International Publication No. WO 2023/180553 A1 on Sep. 28, 2023, and claims the priority of the German first filing DE 10 2022 106 938.9 filed Mar. 24, 2022, the disclosures of all of which are hereby incorporated by reference in their entireties.

### FIELD

The present invention relates to a stacked laser arrangement and a method for producing such a laser array.

### BACKGROUND

For various applications, including virtual reality or augmented reality, laser diodes are used to generate visual information, the light from which is guided to the user's eye via suitable optics. Various laser diodes are used for the red, green and blue color range by placing them on a corresponding carrier and, if necessary, aligning them precisely with the optics.

The conventional manufacturing techniques required for this are often complex and expensive. In addition, the laser diodes arranged on a circuit board require complex optics in order to correctly align the different colors on the user's lens. Although these so-called squint angles can be compensated for by suitable lenses, these are often larger, which is undesirable for smaller applications, e.g. for spectacles.

There is therefore a need to find a space-saving solution for laser arrangements, especially for the virtual reality or augmented reality sector, which can also be implemented cost-effectively.

### SUMMARY OF THE INVENTION

This need is met by the objects of the independent patent claims. Further developments and embodiments of the proposed principle are given in the sub-claims.

The inventors propose stacking several laser devices in a suitable form with spacers arranged between them in such a way that an easy-to-process and space-saving arrangement is created. This makes it possible to use the spacers for contacting the laser arrangements. Due to the low thickness, a stack with very small dimensions can be realized. The spacers can be contacted by various means, whereby a different resonator length can also be utilized. In addition, various stacked devices can be created in this way, i.e. laser devices with single ridges but also with multiple ridges. Depending on the desired light output power, the number of stacked laser arrangements of individual colors can be varied.

In one proposed aspect, a stacked laser arrangement comprises a first laser device with a light exit side and a semiconductor body forming a resonator with an active zone and with two main sides and side surfaces arranged substantially perpendicular thereto. The laser device comprises at least one contact area on a first of the two main sides, for example in the form of a contact surface. In addition, a first spacer with a first main contact side and a contact side surface is provided, wherein the first main contact side comprises at least one contact line which leads from a contact area to a connection surface on or adjacent to the contact side surface. According to the proposed principle, the first laser device is now attached to the first spacer with the first main side facing the first contact main side. The at least one contact area of the laser device is electrically connected to the contact area of the first main contact side of the spacer, and the side surfaces of the first laser device are spaced apart from the contact side surface. This arrangement allows the stacked laser arrangement to be placed directly on a carrier and supplied with power via the contacts on the main contact side of the spacer.

Stacking laser devices with the special spacer design enables 90 degree offset or even vertical mounting with simultaneous electrical contacting to single or multiple edge emitting laser diodes to the nearest electromechanical interface of the carrier. This results in an emission distance of half the laser thickness and the thickness of the spacer or less, depending on the position of the laser beam.

In some aspects, laser devices are provided for this purpose which, in operation, generate a beam with a radiation profile which comprises a fast axis and a slow axis, i.e. is elliptical in shape. The proposed laser arrangement ensures that the fast axis is essentially perpendicular to the main contact side. As a result, when installing such a laser arrangement with one or more devices on a carrier, the fast axis of the radiation profile runs parallel to a surface of the carrier, which allows particularly close mounting on the carrier and thus simplifies the arrangement of further elements.

In some further aspects, the contact side surface comprises a beveled area on which the connection surface is arranged. Depending on the requirements and needs, the connection surface can be designed differently on the contact side surface. In some aspects, the contact side surface is flat and the connection surface is designed as a simple metal layer, for example. In another embodiment, the contact side surface comprises one or more notches or recesses in which the connection surface is arranged. A notch comprises the property of providing a slightly larger surface area. In this way, a slight variation in the amount of solder or other conductive interconnect material can be tolerated, as excess material can remain in the recess. It is also possible to achieve precise positioning on a carrier using a corresponding pin that fits into the notch or recess.

A further aspect relates to the configuration of the geometric dimensions of the spacer and the laser device. In some aspects, a length of the first spacer is less than a length of the first laser device. The laser device thus protrudes beyond the spacer. This protrusion can occur both adjacent to the light emitting side and on the side facing away. In this embodiment, the first spacer is thus set back with respect to the light emission side.

Some further aspects deal with the stacking of several such laser devices and/or several spacers arranged on both sides of the device. This enables, on the one hand, flexible mounting (the contacts for the laser device can also be arranged on different sides of the laser device), and, on the other hand, stacking or combining several such arrangements. In one aspect, the first laser device comprises at least one contact area on a second of the two main sides.

A second spacer is provided with a first main contact side and a contact side surface, wherein the main contact side comprises at least one contact line which leads from a contact area to a connection surface on or adjacent to the contact side surface. The second spacer is thus designed similarly or identically to the first spacer. The orientation of the stacked laser arrangement can also be identified by different designs of the connection surface of the two spacers. According to the proposed principle, the first laser device is now attached with the second main side to the first main contact side of the second spacer. The at least one contact area of the second main side is also electrically conductively connected to the contact area of the first main contact side of the second spacer. Likewise, the side surfaces of the first laser device can optionally be spaced apart from the contact side surface of the second spacer. In particular, the two spacers can have the same dimensions so that the contact side surfaces are at the same distance from the laser device and are therefore at the same height. This enables precise and level positioning on a carrier.

In another embodiment, the first spacer comprises a second main contact side opposite the first main contact side with at least one contact area and a contact line connected thereto. The spacer is thus equipped with contact lugs or contact areas on both sides and thus allows two laser devices to be attached to it. Accordingly, a second laser device is provided in one embodiment, which comprises a light emission side and a semiconductor body forming a resonator with an active zone, two main sides and side surfaces arranged essentially perpendicular to it. The laser device comprises at least one contact area on a first of the two main sides. It is now attached to the first spacer with the first main side facing the second main contact side of the first spacer.

Likewise, the at least one contact area is electrically connected to the contact area of the second main contact side of the first spacer, and the side surfaces of the second laser device are spaced apart from the contact side surface of the first spacer.

Some further aspects relate to the design of the spacers. For example, they can be made from a dielectric material that comprises one or more conductive contact lugs or conductors on its surface. The conductive areas comprise a metallic layer, a metallic layer sequence or another conductive material. Alternatively, a semiconductor material such as silicon or a ceramic such as AlN can also be used. Generally, a thickness of the spacers is less than a thickness of the first and/or second laser arrangement attached to the main contact side.

Another aspect is the use of laser devices themselves as spacers, provided that they comprise the same contact structure as the spacers described above. In one embodiment, the first and/or the second spacer is thus formed by a third laser device with a light-emitting side and a semiconductor body forming a resonator with an active zone and with two main sides and side surfaces arranged substantially perpendicular thereto.

According to the proposed principle, a length of the third laser device is shorter than a length of one of the first and second laser devices but longer than a length of the other of the first and second laser devices. The different lengths allow contact areas to be provided on the exposed portion of the third laser device, which contact the laser device connected to this side, i.e. the first or second laser device. For this purpose, metallic contact lines can be provided on one of the main sides, which in turn are insulated from the semiconductor body of the third laser device. In other aspects, the n- or p-doped sides form common connection surfaces. Thus, in some aspects, an insulated n-doped side of the semiconductor body of the third laser device contacts a p-doped side from the first and/or second laser device. Alternatively, an isolated p-doped side of the semiconductor body of the third laser device may contact an n-doped side from the first and/or second laser device.

In some further aspects, the first and/or the second laser device can also be designed as a spacer. In this way, a stack of laser devices can be created, with some of the laser devices also forming spacers.

A further aspect relates to a method for generating a stacked laser arrangement. A first laser device is provided. This comprises a light-emitting side and a semiconductor body forming a resonator with an active zone, and with two main sides and side surfaces arranged essentially perpendicularly thereto. The first laser device also comprises at least one contact area for electrical connection on a first of the two main sides. In addition, a first spacer with a first main contact side and a contact side surface is provided. The main contact side comprises at least one contact line that leads from a contact area to a connection surface on or adjacent to the contact side surface. As already explained above, the connection surface can assume various shapes and structures.

In a subsequent step, contact areas of the first laser device and the spacer are aligned with each other. The main side of the first laser device, which comprises the contact area, is then attached to the first main side of the spacer, and the contact areas of the first laser device and the spacer are conductively connected to each other. The side surfaces of the first laser device are spaced apart from the contact side surface. This arrangement allows the stacked laser arrangement to be placed directly on a carrier and supplied with power via the contacts on the main contact side of the spacer. The laser device is not “in the way”.

In a further example, the spacer with the contact side surface is arranged on a carrier in such a way that a fast axis of a radiation profile emitted during operation of the laser device runs essentially parallel to a surface of the carrier. This avoids a possible downward limitation of the laser beam.

In one embodiment of the method, the first laser device comprises at least one contact area on a second of the two main sides. According to the proposed principle, a second spacer is provided with a first main contact side and a contact side surface. The contact main side also comprises at least one contact line leading from a contact area to a connection surface on or adjacent to the contact side surface. The second spacer and the first laser device are now attached to each other. This is done in such a way that the first laser device is aligned with the second main side facing the first main contact side of the second spacer and the at least one contact area of the second main side is electrically connected to the contact area of the first main contact side of the second spacer. The laser device is also mechanically attached to the spacer, either by the electrical connection (for example by means of a solder) or by an adhesive or the like. The side surfaces of the first laser device are spaced apart from the contact side surface.

In another example, the first spacer comprises a second main contact side opposite the first main contact side with at least one contact line. A second laser device is now provided here with a light emission side and a semiconductor body forming a resonator, wherein the semiconductor body comprises an active zone, two main sides and side surfaces arranged essentially perpendicularly thereto. In addition, the laser device comprises at least one contact area on a first of the two main sides. The first spacer and the second laser device are aligned with each other and attached to each other in such a way that the second laser device lies with the first main side facing the second main contact side of the first spacer. At the same time, the at least one contact area of the laser device is electrically conductively connected to the contact area of the second main contact side of the first spacer and the side surfaces of the second laser device are spaced apart from the contact side surface.

Some aspects deal with a design of the first and/or second spacer. For example, a recess, indentation or notch can be provided here, which can be produced by etching, milling, laser cutting or other measures. This element extends from the first main contact side in the direction of the second main contact side. A contact line is also created, in particular as a metallic layer that extends from the contact area to the recess. The recess or indentation can also be metallized. The contact surface is also created on the main contact side.

In some aspects, the first and/or second spacer is thinner or of the same thickness as the laser devices. It can be made of a dielectric material, for example a ceramic. This in turn can be processed at wafer level and structured with the contact surfaces. The spacers are then cut from the wafer composite.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a first embodiment of a stacked laser arrangement in cross-section with some aspects according to the proposed principle;

FIG. 2 shows the first embodiment of FIG. 1 in plan view to explain some aspects according to the proposed principle;

FIGS. 3 and 4 show process steps for a method for processing such stacked laser arrangements according to the proposed principle;

FIG. 5 shows a perspective view of a plurality of spacers for creating a stacked laser arrangement according to some aspects of the proposed principle;

FIG. 6 shows a cross-section of a stacked laser arrangement with a spacer as shown in FIG. 5 to illustrate some aspects of the proposed principle;

FIG. 7 shows a perspective view of a version of a spacer for generating a stacked laser arrangement according to some aspects of the proposed principle;

FIG. 8 shows an embodiment of a stacked laser arrangement with a spacer of FIG. 7 to explain some aspects of the proposed principle;

FIG. 9 shows a perspective view of a variation of an embodiment with some aspects of the proposed principle;

FIG. 10 shows a front view of the design shown in FIG. 9;

FIG. 11 is a top view of an embodiment of a stacked laser arrangement according to some aspects of the proposed principle;

FIG. 12 shows a top view of a further embodiment of a stacked laser arrangement according to some aspects of the proposed principle;

FIG. 13 shows a top view of a further embodiment of a stacked laser arrangement according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

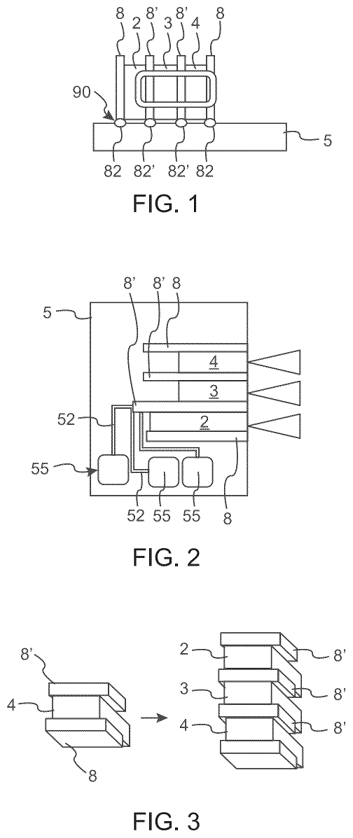

FIG. 1 shows a first embodiment of a stacked laser arrangement according to the proposed principle, which is mounted on a carrier. The stacked laser arrangement comprises a total of three laser devices, 2, 3 and 4, which are designed to emit laser light of different wavelengths. The individual laser devices are designed in such a way that a contact surface is provided on their respective main sides. In the embodiment example of FIG. 1, these main sides are the sides running perpendicular to the carrier 5. Spacer elements 8′ are arranged between the individual laser devices. The laser device 2 is also mechanically and electrically connected to a further spacer 8 on its outward-facing main side. A spacer 8 is also attached to the laser device 4 on its outward-facing main side.

The spacers 8′ 8 comprise one or more leads on their respective surfaces, which are electrically conductively connected to the contact areas on the main sides of the laser device 2, 3 and 4. The contact leads on the spacers lead to connection surfaces 82 or 82′ on the side surfaces of the spacers facing the carrier 50. These contact surfaces connect the spacer mechanically and electrically to the corresponding contact surfaces of the carrier 5. As shown in FIG. 1, there is a slight gap 90 between the lower side surfaces of the laser devices 2, 3 and 4 and the surface of the carrier 5. In other words, the side surfaces of the corresponding laser devices 2, 3 and 4 are thus set back with respect to the lower side surfaces of the spacers 8 and 8′. In this way, a laser arrangement is created whose beam characteristics and light profile lie within the area represented by the rectangle 100. This makes it possible, for example, to provide a stacked laser arrangement for RGB displays on a carrier in a very space-saving manner.

FIG. 2 shows a top view of the embodiment of FIG. 1. The carrier 5 comprises one or more feed lines 52 on its surface, which in turn are coupled to electronic circuits 55 on the surface and the like. The individual spacers 8′ and 8 of the laser arrangement are each designed with different lengths in order to accommodate the different resonance lengths of the respective laser devices 2, 3 and 4. The longer length serves as an additional heat sink in order to quickly dissipate and radiate the heat generated during operation of the laser devices. In the embodiment example of FIGS. 1 and 2, the length of the spacers 8′ and 8 are selected so that they are slightly longer than the corresponding resonators or longer than the semiconductor bodies of the laser devices. The end of the spacers facing away from the light emission side protrudes beyond the semiconductor bodies of the laser devices, for the improved heat dissipation mentioned above. At the same time, the side of the spacers facing the light-emitting surface of the laser devices is set back slightly so that the light-emitting surfaces of the laser devices are flush with the side edge of the carrier 5.

For contacting the individual laser devices, a contact line can be formed on a side surface of the spacer 8 or 8′. For example, a contact surface can be prepared on the side of the spacer 8 or 8′ facing the laser device, which is electrically conductively connected to the corresponding contact area of the laser device. In some embodiments, this results in the spacer 8′ having a contact lead and a contact area on each of its main sides, while the spacers 8 only have such an area on one of their two main sides. The contact areas lead along the main side via leads to connection surfaces in or on the side surface of the respective spacer.

Alternatively, it is also possible, for example, to equip the two outer spacers 8 without a contact, provided that the laser devices 4 or 2 are only contacted via one of their main sides. In this case, the two spacers 8′ each comprise two contact areas, which are opposite the main side facing the laser device 2 or 4. The respective other side of the spacer elements 8′ also comprises either one contact area or two contact areas or no contact areas at all, depending on the design of the laser device 3. This allows a very flexible design and structuring of the various spacers 8′ according to the requirements and design of the laser devices to be stacked on top of each other. A spacer can thus have either none, one or several contact areas on its surface. Likewise, one or more contact areas can be provided on the opposite main side of the spacer. The contact areas lead via contact lines to corresponding connection surfaces on the side surface, with which the spacer is then placed on a PCB board, an intermediate carrier or another element and fastened mechanically and electrically.

FIGS. 5 and 6 show a somewhat more detailed design example of such a spacer, as prepared for the manufacture of stacked laser arrangements, for example. FIG. 5 shows such a support 5, which comprises a series of parallel recesses 83. These lead from a main side at a slant to a certain depth, for example half the thickness of the respective carrier 5. A connection surface is provided in the middle of this recess, which extends along the slanted edge to the main side of the carrier 5 and merges there into the contact area 84. In the illustration in FIG. 5, three such contact areas 84 and three connecting surfaces coupled to them are provided in the recesses. The recesses are separated from one another in a manufacturing step, so that separate spacers are produced which comprise a contact area 84 on a main surface, which extends along the main side up to a connection surface located on a side surface. FIG. 6 shows the cross-sectional representation of such a spacer 8 in its mounted state on a carrier 5. In this cross-sectional representation, the spacer comprises a beveled side surface that opens from a lower side surface of the spacer 8 towards the main side. The angle of this opening is approximately 45° in the present embodiment example, but can also be larger or smaller. As already shown in the preceding embodiment example of FIG. 5, the beveled shape extends approximately up to half the thickness of the spacer 8.

On the main side, a laser device 4 with its contact is applied to the contact area 84 and mechanically and electrically attached thereto. An attachment of an electrical and mechanical nature to a carrier 5 is achieved via a solder material 81, which fills the space between a contact surface 56 on the carrier 5 and the connection surface 82 on the beveled side. On the one hand, the solder material creates an electrical connection and, on the other, also leads to improved mechanical retention. For further improvement, an additional adhesive or similar can be provided on the side facing away from the laser device to further strengthen and improve the mechanical mounting.

The beveled side surface makes it possible to compensate for variations in the amount of solder material 81 used. Depending on the amount of solder, this fills the space between the contact 56 on the carrier 5 and the connection surface 82 more or less completely. However, the bevel ensures that the spacer is correctly aligned with its lowest area and arranged vertically on the carrier 5.

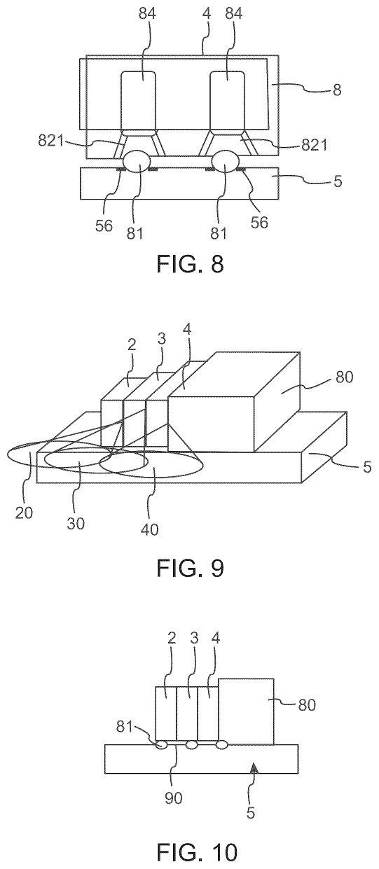

This design can be varied with additional contact areas on the side surface. FIGS. 7 and 8 show an embodiment in which one or more indentations 821 are provided instead of a continuous recess. These indentations on the upper side of a spacer 8 are provided with a metallic layer, which in turn are in conductive contact with the contact area 84 on the main side of the spacer. FIG. 7 shows such an embodiment of a spacer during production. Here, two notches 821 are provided in a ceramic platelet and then provided with a metallization layer. This metallization layer extends from the indentations 828 to a main side of the ceramic platelet and forms the contact areas 84 there. The ceramic platelet is then cut in a suitable shape so that the indentations form parts of the lower side surface.

FIG. 8 now shows a top view of such a spacer with a laser device arranged on it. The laser device comprises two contact areas on one of its main sides and is mechanically attached to the spacer 8. The contact areas on the laser device are opposite the contact areas 84 on the spacer and connect them electrically. As can also be seen in this embodiment example, the indentations 821 form a kind of pocket into which the solder material 81 can be filled in order to electrically connect the contact areas 56 on the surface of the carrier with the metallization layer in the indentations 821 and thus with the contact areas. Here too, in a final state, the spacer is placed firmly on the carrier 5, the solder material is melted on and thus an intimate connection is created between the contact surfaces of the 56 on the upper side and the contact areas 84.

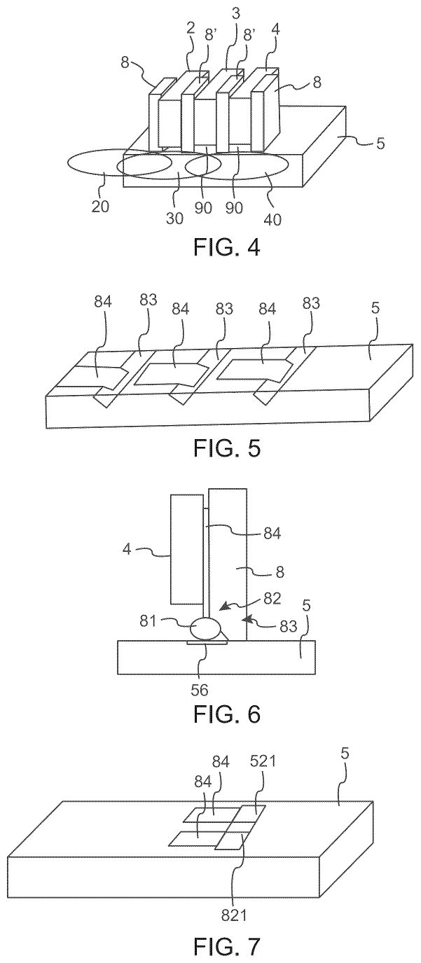

The design of the spacers shown in FIGS. 5 and 7 can now be used to create a stacked laser arrangement in order to subsequently arrange it on a carrier in a further process control step. FIGS. 3 and 4 show an embodiment of such a process. At least one laser device 4 is provided in FIG. 3, which has one or more contact areas on its lower or upper main side.

The spacers already explained in FIGS. 5 and 7 are also created and provided. In a subsequent step, the laser device is applied to one of these spacers by aligning the contact areas with each other. The contact areas are then electrically connected to each other and the laser device is mechanically attached to the spacer. The width of the spacer 8 is selected so that its lower side edge provided with the contact areas projects beyond the corresponding side surface of the laser device. To stagger further laser devices, a further spacer 8′ can be placed on the upper main side of the laser device 4 and mechanically or mechanically and electrically connected to it, as shown in the embodiment example in FIG. 3. This procedure can now be repeated several times until the stacked laser arrangement shown in the righthand partial figure is created. The stacked laser arrangement now comprises a plurality of laser devices, with a spacer element 8 or 8′ located between each two laser devices. In the embodiment example, the lower side surfaces of the spacer elements 8 and 8′ project beyond the respective adjacent side surfaces of the laser device.

The laser devices shown in these embodiments are designed as edge-emitting lasers. The radiation profile of such edge-emitting lasers is elliptical and comprises a so-called fast axis and a corresponding slow axis. The fast axis corresponds to the large main axis of the elliptical radiation profile, while the slow axis corresponds to the small main axis. This results in a radiation profile with a propagation that is lower parallel to the main sides of the respective laser devices than perpendicular to them. For this reason, in some embodiments, the stacked laser arrangement generated here is now rotated by 90° and thus applied offset to a carrier 5. One such embodiment is shown in FIG. 4. Due to the 90° offset arrangement, the large main axis or the fast axis of the radiation profile 20, 30 and 40 of the laser devices 2, 3 and 4 is parallel to the surface of the carrier. At the same time, there is a slight distance between the surface of the carrier 5 and the lower side surface of the respective laser devices 2, 3 and 4 due to the previous arrangement of the laser devices to the lower side surface of the spacer elements. This allows the spacer elements to be placed carefully on the contact surfaces of the carrier 5 and the existing solder to be melted cleanly without it coming into contact with the side surfaces of the laser and thus causing a short circuit or mechanical displacement or twisting.

In a further embodiment, the proposed concept is now supplemented by using a laser device itself as a spacer, which further reduces the width of the individual elements. FIG. 9 shows a first embodiment in which the laser devices are stacked directly on top of one another and arranged on a common submount 80. The submount 80 is also regarded as a spacer.

Specifically, the laser device 4 is attached to the submount 80, the laser device 3 is located directly on the laser device 4 and the laser device 2 is located on the laser device 3. The individual laser devices comprise the same width so that their respective side surfaces are flush with each other. However, the laser devices are also less wide than the submount 80 on which the laser device 4 is mounted. This results in a slight gap between the side surface of the submount 80 and the corresponding side surfaces of the laser devices 2, 3 and 4 arranged on it.

For mounting on a carrier 5 as shown in FIG. 9, the arrangement manufactured in this way is rotated by 90° and then attached to the carrier substrate 5 with the side surface of the submount 80. Due to the small distance between the side surfaces, there is a small distance between the surface of the carrier 5 and the individual laser devices. This is in the range of a few μm and serves, among other things, to compensate for heat-related expansion of the carrier or the laser devices so that they are not exposed to additional mechanical stress during operation.

At the same time, the radiation profile of the individual laser devices is also rotated by 90° so that the radiation profiles 20, 30 and 40 now lie with their fast axis parallel to the surface of the carrier 5.

In this way, even in the rotated arrangement shown here, the laser devices can be very flat, i.e. with only a small height.

The distance 90 shown in the view of FIG. 10 is selected so that contacts on the upper side of the carrier 5 can be guided to corresponding connection areas on the laser devices by means of solders. For this purpose, the laser devices 3 and 4 as well as the submount 80 comprise one or more contact feeders on their exposed area, which are similar in design, shape and construction to the embodiments of the spacers shown above.

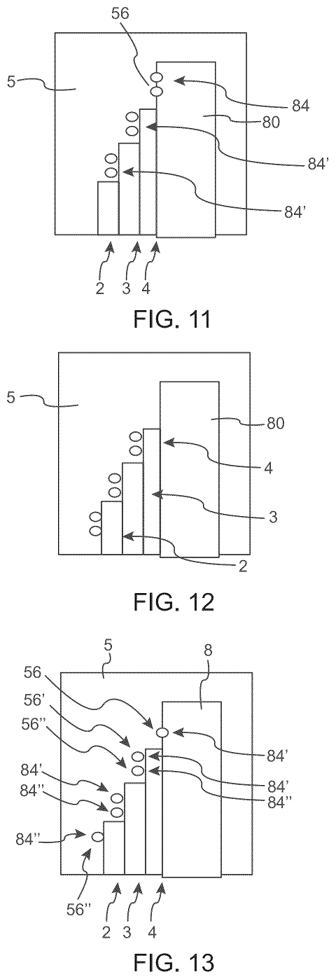

In this respect, FIG. 11 shows a top view of the laser arrangement according to the proposed principle. The submount 80 comprises two contact lines 84 on its area facing away from the light-emitting surface. These extend to the underside of the submount 80, where they make electrical contact with corresponding areas 56 on the surface of the carrier 5. A connection is made via a solder material. The supply lines 84 on the submount 80 lead to the underside of the laser device 4 and make contact there with connections for the laser device 4. An insulating material is applied to the upper side of the laser device 4, and further supply lines 84′ are arranged on this in the form of metallization layers. These metallization layers also run up to a side edge of the laser device 4 facing the carrier 5 and form a contact surface there for making contact with a corresponding contact area arranged on the carrier by means of a solder material 81. These leads 84′ also run along the insulated surface of the laser device 4 up to contacts of the laser device 3 on the side facing the laser device 4.

In the same way, the surface of the laser device 3 is also insulated and metallization layers are formed on it. The different resonator length of the devices 2, 3 and 4 ensures that the contact lines run essentially vertically downwards towards the carrier surface and can contact the contact surfaces 56 on the upper side of the carrier via a solder material without another laser device being in the way. The different resonance length can also be used to define the color sequence of the individual laser devices of the laser arrangement.

Another embodiment of a stacked laser arrangement is shown in FIG. 12, in which some laser devices simultaneously form the spacer for the following laser devices. In this arrangement, the individual laser devices are designed so that their respective surfaces are made of an insulating material. As a result, the laser devices can be arranged directly on top of each other as shown in FIG. 12 without the risk of a short circuit. In this embodiment, the supply lines for the individual laser devices are provided in the form of metallization layers on the respective upper side of the corresponding laser device. As shown, the supply lines run along the surface into the drawing plane until they form a contact surface on the side surface of the respective laser device facing the carrier for contacting with contact surfaces on the surface of the carrier 5. The embodiment thus comprises the two connection contacts of each laser device on the upper side of the respective laser. Furthermore, the arrangement shown in the embodiment example is stacked in such a way that an isolated n-doped side of the semiconductor body of one laser contacts a p-doped side of the semiconductor body of the laser device below it, i.e. the laser device to the right of it.

In a further embodiment, these aspects can be combined with each other. FIG. 13 shows such an embodiment in which the contacts for a laser device are located partly on this laser device and partly on an upstream laser device or on the submount. In particular, as in the previous figures, the laser devices 2, 3 and 4 are stacked on top of each other with different resonance lengths and the laser device 4 is arranged on a submount 8. Like submounts 80, this is designed as a spacer element. A metallization layer is now applied to one side of the submount 8, which extends into the drawing plane and makes contact with a contact surface 56 on the upper side of the carrier 5.

The contact surface on the side surface of the spacer 8 leads to a contact line that electrically connects a contact on the rear of the laser device 4 for feeding charge carriers. In contrast to the previous embodiments, this design now allows a more flexible and different arrangement of the laser devices on top of each other.

In one possible embodiment, a first contact line and a second contact line are arranged on the upper side of the laser device 4, which electrically connect the contact surfaces 56′ and 56″ on the carrier surface. The first and second lines are also implemented as metallic conductor layers 84′ and 84″, with the first conductor layer also directly forming the second contact for the laser device 4. The contact line 84″, which connects the contact area 56″, is insulated from the laser device 4 and in turn leads to the rear of the laser device 3, where it makes electrical contact with it. The upper side of the laser device 3 is designed in the same way and comprises a first contact line 84′, which is designed as a feed line for the laser device 3.

A second contact line 84″ in the form of a metallization layer again forms the supply line for the contact of the laser device 2 on the rear side of the laser device. Finally, a last contact area 56″ on the upper side of the carrier 5 is connected to a contact line 84″. In this way, a contact line is provided on the upper side of a laser device, which contacts the laser device itself, as well as a further contact line, which leads as an insulated metallization layer to the rear side of an adjacent laser device arranged thereon.

In an alternative embodiment, however, the laser devices can also be constructed differently so that they face each other in pairs. This is done in such a way that two contacts each contain the same potential.

For example, the n-doped side of the semiconductor body of the laser device 4 faces the submount 8, while the p-doped side of the semiconductor body of the device faces the laser device 3. The side of the laser device 3 that faces the device 4 is also the p-doped side. In this way, the first contact lines 84′ and 84″ on the upper side of the laser device 4 can be connected to a common potential or can also be designed as a common feed. The reason for this is that the p-doped sides of the two laser devices 3 and 4 are opposite each other.

The upper side of the laser device 3 is now the n-doped side. Accordingly, the device 2 is now arranged so that the n-doped side of the laser device 2 is again opposite the upper side of the laser device 3.

Accordingly, the contacts 84″ and 84′ on the upper side of the laser device 3 can also be suitably connected to a potential. In this embodiment, the insulated rear side of a laser device is thus used to realize a contact feed to the “own” semiconductor body on the one hand, but also a feed to the semiconductor body of a neighboring laser device, with the sides facing each other being doped in the same way.

1. A stacked laser arrangement, comprising:
a first laser device comprising a light-emitting side and a semiconductor body forming a resonator and with an active zone and with two main sides and side surfaces arranged substantially perpendicularly thereto; the laser device having at least one contact region on a first of the two main sides; and
a first spacer comprising a first contact main side and a contact side surface; the contact main side comprising at least one contact line leading from a contact area to a terminal surface on or adjacent to the contact side surface; wherein
the first laser device is attached to the first spacer with the first main side facing the first contact main side, so that the at least one contact area is electrically connected to the contact area of the first contact main side and the side surfaces of the first laser device are spaced apart from the contact side surface, and
wherein a length of the first spacer is less than a length of the first laser device and the first spacer is recessed with respect to the light emitting side.

2. The stacked laser arrangement according to claim 1, wherein a radiation profile emitted during operation of the laser device comprises a fast axis substantially perpendicular to the main contact side.

3. The stacked laser arrangement according to claim 1, wherein the contact side surface comprises a beveled area on which the connection surface is arranged.

4. (canceled)

5. The stacked laser arrangement according to claim 1, wherein the first laser device comprises at least one contact region on a second of the two main sides; and further comprising:
a second spacer comprising a first contact main side and a contact side surface; the contact main side having at least one contact line leading from a contact area to a terminal surface on or adjacent to the contact side surface; wherein
the first laser device is attached to the second spacer with the second main side facing the first main contact side of the second spacer, so that the at least one contact region of the second main side is electrically connected to the contact region of the first main contact side of the second spacer and the side surfaces of the first laser device are spaced apart from the contact side surface of the second spacer.

6. The stacked laser arrangement according to claim 1, wherein the first spacer comprises a second contact main side opposite the first contact main side with at least one contact area and a contact line connected thereto; the stacked laser arrangement further comprising:
a second laser device having a light emitting side and a semiconductor body forming a resonator with an active zone and having two main sides and side surfaces arranged substantially perpendicular thereto; the second laser device having at least one contact region on a first of the two main sides; and
the second laser device is attached to the first spacer with the first main side facing the second main contact side of the first spacer, so that the at least one contact area is electrically connected to the contact area of the second main contact side of the first spacer and the side surfaces of the second laser device are spaced apart from the contact side surface of the first spacer.

7. The stacked laser arrangement according to claim 1, wherein the first and/or the second spacer is formed by a third laser device having a light emitting side and a semiconductor body forming a resonator having an active region and comprising two main sides and side faces substantially perpendicular thereto; wherein a length of the third laser device is shorter than a length of one of the first and second laser devices and longer than a length of the other of the first and second laser devices.

8. The stacked laser arrangement according to claim 7, wherein an isolated n-doped side of the semiconductor body of the third laser device contacts a p-doped side from the first and/or second laser device; or wherein an isolated p-doped side of the semiconductor body of the third laser device contacts an n-doped side from the first and/or second laser device.

9. The stacked laser arrangement according to claim 7, wherein the third laser device comprises, on a region of the first contact main side facing away from the light emitting surface, at least one contact line leading from a contact region to a connection surface on or adjacent to a side surface of the third laser device.

10. The stacked laser arrangement according to claim 1, wherein the contact side surface of the first and/or second spacer comprises a recess extending from the first contact main side towards the second contact main side and at least partially comprises a metallic layer forming the contact line.

11. The stacked laser arrangement according to claim 1, wherein first and/or second spacers comprise at least one of the following materials:
a dielectric material;
a semiconductor material with at least one dielectric surface, in particular on the main contact sides; and
a semiconductor material, in particular silicon or AlN, with regions of SiO2.

12. The stacked laser arrangement according to claim 1, wherein the spacer comprises a thickness thinner than a thickness of the first and/or second laser arrangement attached to the contact main side.

13. A method of generating a stacked laser arrangement comprising:
providing a first laser device having a light emitting side and a semiconductor body forming a resonator having an active zone and having two main sides and side surfaces arranged substantially perpendicular thereto, the laser device having at least one contact region on a first of the two main sides;
providing a first spacer having a first contact main side and a contact side surface, wherein the contact main side comprises at least one contact line leading from a contact area to a connection surface on or adjacent to the contact side surface;
aligning the main side of the first laser device having the contact area with the first main side of the spacer; and
attaching the first laser device to the spacer in such a way that the at least one contact area is electrically conductively connected to the contact area of the spacer and side surfaces of the first laser device are spaced apart from the contact side surface.

14. The method according to claim 13, further comprising
mounting the spacer with the contact side surface on a support such that a fast axis of a radiation profile emitted during operation of the laser device is substantially parallel to a surface of the support.

15. The method of claim 13, wherein the first laser device comprises at least one contact area on a second one of the two main sides, and further comprising:
providing a second spacer having a first contact main side and a contact side surface, wherein the contact main side comprises at least one contact line leading from a contact area to a terminal surface on or adjacent to the contact side surface; and
attaching the second spacer and the first laser device to each other such that the first laser device is attached to the second spacer with the second main side facing the first main contact side of the second spacer, so that the at least one contact area of the second main side is electrically connected to the contact area of the first main contact side of the second spacer and the side surfaces of the first laser device are spaced apart from the contact side surface.

16. The method of claim 13, wherein the first spacer comprises a second main contact side opposite the first main contact side having at least one contact line, and the method further comprising:
providing a second laser device having a light emitting side and a semiconductor body forming a resonator having an active zone and having two main sides and side surfaces arranged substantially perpendicular thereto; the laser device having at least one contact region on a first of the two main sides; and
attaching the first spacer and the second laser device to each other such that the second laser device is attached to the first spacer with the first main side facing the second main contact side of the first spacer, so that the at least one contact area is electrically connected to the contact area of the second main contact side of the first spacer and the side surfaces of the second laser device are spaced apart from the contact side surface.

17. The method of claim 13, wherein providing the first and/or second spacer comprises:
forming a recess on the contact side surface of the first and/or second spacer extending from the first contact main side towards the second contact main side; and
forming a contact line, in particular as a metallic layer, which runs from the contact area to the recess.

18. The method of claim 13, wherein the first and/or second spacer comprises a thickness thinner than a thickness of the first and/or second laser device attached to the contact main side and optionally comprises at least one of the following materials:
a dielectric material;
a semiconductor material with at least one dielectric surface, in particular on the main contact sides; and
a semiconductor material, in particular silicon or AlN, with regions of SiO2.
